(19) United States
(12) Patent Application Publication
(10) Pub. No.: US 2009/0072277 A1
(43) Pub. Date: Mar. 19, 2009

(54) System and Method for Enabling Higher Hole Mobility in a JFET

(75) Inventor: Srinivasa R. Banna, San Jose, CA (US)

Correspondence Address: BAKER BOTTS L.L.P., 2001 ROSS AVENUE, SUITE 600, DALLAS, TX, 75201-2980, US

(73) Assignee: DSM Solutions, Inc.

(21) Appl. No.: 11/856,240

(22) Filed: Sep. 17, 2007

(51) Int. Cl. H01L 29/80; H01L 21/337

(52) U.S. Cl. 257/256; 438/187; 257/E29.242; 257/E21.445

(57) ABSTRACT

A junction field effect transistor comprises a semiconductor wafer having a (110) and/or (100) surface orientation. A source region and a drain region are formed on the semiconductor wafer. A channel region of a p-conductivity type is formed between the source region and the drain region. The channel region is oriented along a <110> and/or <100> direction of the semiconductor wafer.

### TECHNICAL FIELD OF THE INVENTION

This invention relates in general to semiconductor devices, and more particularly to a system and method for enabling higher hole mobility in a JFET.

### BACKGROUND OF THE INVENTION

A Junction Field Effect Transistor (JFET) that operates with a low gate capacitance, C, and a low gate voltage, V, will have a low charge, Q, because Q=C*V. The drive current of a JFET, I, is the product of charge, Q, and the velocity of charge carriers, v, because I=Q*v. Thus, in order to increase drive current, I, given a low charge, Q, the velocity of the charge carriers, v, should be increased.

### SUMMARY OF THE INVENTION

In accordance with the present invention, the disadvantages and problems associated with prior JFET devices have been reduced or eliminated.

A junction field effect transistor comprises a semiconductor wafer having a (110) surface orientation. A source region and a drain region are formed on the semiconductor wafer. A channel region of a p-conductivity type is formed between the source region and the drain region. The channel region is oriented along a <110> direction of the semiconductor wafer.

A method for forming a junction field effect transistor comprises providing a semiconductor wafer having a (110) surface orientation and a <110> notch orientation. The method continues by forming a source region and a drain region on the semiconductor wafer. The method continues further by forming a channel region of a p-conductivity type between the source region and the drain region. The channel region is oriented along a <110> direction of the semiconductor wafer. The method concludes by forming a gate region of an n-conductivity type.

A junction field effect transistor comprises a semiconductor wafer having a (110) surface orientation. A source region and a drain region are formed on the semiconductor wafer. A channel region of a p-conductivity type is formed between the source region and the drain region. The channel region is oriented along a <100> direction of the semiconductor wafer.

A method for forming a junction field effect transistor comprises providing a semiconductor wafer having a (110) surface orientation and a <100> notch orientation. The method continues by forming a source region and a drain region on the semiconductor wafer. The method continues further by forming a channel region of a p-conductivity type between the source region and the drain region. The channel region is oriented along a <100> direction of the semiconductor wafer. The method concludes by forming a gate region of an n-conductivity type.

A junction field effect transistor comprises a semiconductor wafer having a (100) surface orientation. A source region and a drain region are formed on the semiconductor wafer. A channel region of a p-conductivity type is formed between the source region and the drain region. The channel region is oriented in a direction along a <100> direction of the semiconductor wafer.

A method for forming a junction field effect transistor comprises providing a semiconductor wafer having a (100) surface orientation. The method continues by forming a source region and a drain region on the semiconductor wafer. The method continues further by forming a channel region of a p-conductivity type between the source region and the drain region. The channel region is oriented along a <100> direction of the semiconductor wafer. The method concludes by forming a gate region of an n-conductivity type.

The following technical advantages may be achieved by some, none, or all of the embodiments of the present invention.

By orienting the channel of a p-type JFET along a particular direction of a semiconductor wafer based on its surface orientation and/or notch orientation, the hole mobility of the device may be increased. As a result, the drive current of the JFET may be increased.

These and other advantages, features, and objects of the present invention will be more readily understood in view of the following detailed description, drawings, and claims.

### BRIEF DESCRIPTION OF THE DRAWINGS

For a more complete understanding of the present invention and its advantages, reference is now made to the following description, taken in conjunction with the accompanying drawings, in which:

FIG. 1 illustrates one embodiment of a JFET device formed on a semiconductor wafer having a (100) surface orientation and a <100> notch orientation;

FIG. 2 illustrates one embodiment of a JFET device formed on a semiconductor wafer having a (100) surface orientation and a <110> notch orientation;

FIG. 3 illustrates one embodiment of a JFET device formed on a semiconductor wafer having a (110) surface orientation and a <110> notch orientation; and

FIG. 4 illustrates another embodiment of a JFET device formed on a semiconductor wafer having a (110) surface orientation and a <110> notch orientation.

### DETAILED DESCRIPTION OF THE INVENTION

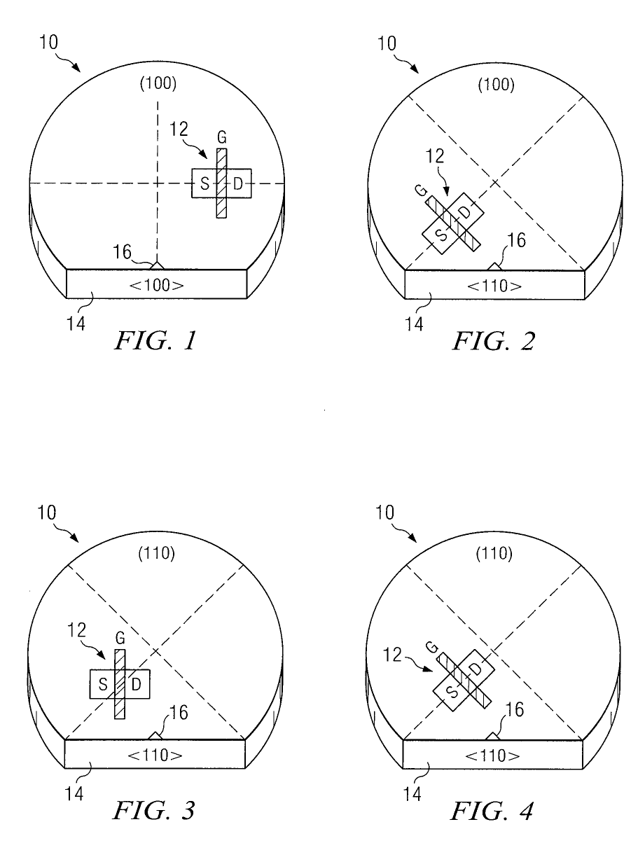

FIG. 1 illustrates a semiconductor wafer 10, such as a silicon crystal, upon which a junction field effect transistor (JFET) 12 is formed. Generally, wafer 10 is cut from an ingot of semiconductor material and polished on one or both faces. Wafer 10 may comprise a flat 14 and/or a notch 16 that indicates crystallographic planes of high symmetry using, in one embodiment, Miller indices. The Miller indices comprise a combination of three digits, either 1 or 0, e.g. (100), (111), etc.; used to define orientation of the crystallographic planes in the silicon crystal.

In the embodiment illustrated in FIG. 1, wafer 10 has a (100) surface orientation and a <100> notch orientation and/or flat orientation. The surface orientation comprises the crystallographic plane, described in terms of its Miller indices, with which the wafer surface is ideally coincident. The flat 14 comprises a portion of the wafer 10 where material is removed along a particular direction. The notch 16 comprises an intentionally fabricated indent of specified shape, dimension, and orientation.

JFET 12 comprises a source region 20, a drain region 22, a gate region 24, and a channel region 26. JFET 12 further comprises source, drain, and gate electrodes that are in ohmic contact with the source region 20, drain region 22, and gate region 24, respectively. In the embodiment illustrated in FIG. 1, channel region 26 of JFET 12 is p-conductivity type and is oriented in a direction substantially parallel to a <100> direction of the wafer 10. Orienting the p-conductivity type channel region 26 along the <100> direction on (100) surface orientation wafer 10 results in an increased drive current for JFET 12. This results, at least in part, because when holes move along the <100> direction of wafer 10, it results in a reduction in the effective mass of the holes. A lower effective mass of the holes results in a higher velocity for the holes. This results in an increase in the p-type JFET 12 drive current as compared to a conventional wafer orientation. Although only a single p-type JFET 12 is illustrated in FIG. 1, it should be understood that any suitable number and combination of p-type or n-type transistors may be formed on wafer 10.

Manufacturing JFET 12 on wafer 10 is straightforward when wafer 10 has a <100> notch orientation (or flat orientation), as with wafer 10 of FIG. 1, because channel region 26 of JFET 12 is generally parallel to the <100> notch orientation. The method for forming a JFET 12 on wafer 10 of FIG. 1 comprises providing a semiconductor wafer having a (100) surface orientation and forming a source region 20 and drain region 22 on wafer 10. The method continues by forming a channel region 26 of a p-conductivity type between the source region 20 and the drain region 22, wherein the channel region 26 is oriented in a direction substantially parallel to a <100> direction of the wafer 10. The method further comprises forming a gate region 24 of an n-conductivity type. The method also includes forming electrodes for the source region 20, drain region 22, and gate region 24. Each of these electrodes is in ohmic contact with its corresponding region.

FIG. 2 illustrates a wafer 10 having a (100) surface orientation and a <110> notch orientation and/or flat orientation. Channel region 26 of JFET 12 is p-conductivity type and is oriented in a direction substantially parallel to a <100> direction of the wafer 10. As in FIG. 1, orienting the p-conductivity type channel region 26 along the <100> direction on (100) surface orientation wafer 10 results in an increased drive current for JFET 12 as compared to a conventional wafer orientation. Again, although only a single p-type JFET 12 is illustrated in FIG. 2, it should be understood that any suitable number and combination of p-type or n-type transistors may be formed on wafer 10.

Manufacturing JFET 12 on wafer 10 could be more complex when wafer 10 has a <110> notch orientation (or flat orientation), as with wafer 10 of FIG. 2, because channel region 26 of JFET 12 is not parallel to, but rather 45 degrees oriented from, the <110> notch orientation. However, a wafer 10 having a <110> notch orientation is more commonly found in industry and may be obtained more cost effectively. The method for forming a JFET 12 on wafer 10 of FIG. 2 comprises providing a semiconductor wafer having a (100) surface orientation and forming a source region 20 and drain region 22 on wafer 10. The method continues by forming a channel region 26 of a p-conductivity type between the source region 20 and the drain region 22, wherein the channel region 26 is oriented in a direction substantially parallel to a <100> direction of the wafer 10. The method further comprises forming a gate region 24 of an n-conductivity type. The method also includes forming electrodes for the source region 20, drain region 22, and gate region 24. Each of these electrodes is in ohmic contact with its corresponding region.

FIG. 3 illustrates a wafer 10 having a (110) surface orientation and a <110> notch orientation and/or flat orientation. Channel region 26 of JFET 12 is p-conductivity type and is oriented in a direction substantially parallel to a <110> direction of the wafer 10. Orienting the p-conductivity type channel region 26 along the <110> direction on (110) surface orientation wafer 10 results in an increased drive current for JFET 12. This results, at least in part, because when holes move along the <110> direction of (110) surface orientation wafer 10, it results in a reduction in the effective mass of the holes. A lower effective mass of the holes results in a higher velocity for the holes. This results in an increase in the p-type JFET 12 drive current as compared to a conventional wafer orientation. Again, although only a single p-type JFET 12 is illustrated in FIG. 3, it should be understood that any suitable number and combination of p-type or n-type transistors may be formed on wafer 10.

Manufacturing JFET 12 on wafer 10 is straightforward when wafer 10 has a <110> notch orientation (or flat orientation), as with wafer 10 of FIG. 3, because channel region 26 of JFET 12 is generally parallel to the <110> notch orientation. The method for forming a JFET 12 on wafer 10 of FIG. 1 comprises providing a semiconductor wafer having a (110) surface orientation and forming a source region 20 and drain region 22 on wafer 10. The method continues by forming a channel region 26 of a p-conductivity type between the source region 20 and the drain region 22, wherein the channel region 26 is oriented in a direction substantially parallel to a <110> direction of the wafer 10. The method further comprises forming a gate region 24 of an n-conductivity type. The method also includes forming electrodes for the source region 20, drain region 22, and gate region 24. Each of these electrodes is in ohmic contact with its corresponding region.

FIG. 4 illustrates a wafer 10 having a (110) surface orientation and a <110> notch orientation and/or flat orientation. Channel region 26 of JFET 12 is p-conductivity type and is oriented in a direction substantially parallel to a <100> direction of the wafer 10. Orienting the p-conductivity type channel region 26 along the <100> direction on (110) surface orientation wafer 10 results in an increased drive current for JFET 12. This results, at least in part, because when holes move along the <100> direction of (110) surface orientation wafer 10, it results in a reduction in the effective mass of the holes. A lower effective mass of the holes results in a higher velocity for the holes. This results in an increase in the p-type JFET 12 drive current as compared to a conventional wafer orientation.

Manufacturing JFET 12 on wafer 10 could be more complex when wafer 10 has a <110> notch orientation (or flat orientation) and channel region 26 is in the <100> direction, as with wafer 10 of FIG. 4, because channel region 26 of JFET 12 is not parallel to, but rather 45 degrees oriented to, the <110> notch orientation. The method for forming a JFET 12 on wafer 10 of FIG. 4 comprises providing a semiconductor wafer having a (110) surface orientation and forming a source region 20 and drain region 22 on wafer 10. The method continues by forming a channel region 26 of a p-conductivity type between the source region 20 and the drain region 22, wherein the channel region 26 is oriented in a direction substantially parallel to a <100> direction of the wafer 10. The method further comprises forming a gate region 24 of an n-conductivity type. The method also includes forming electrodes for the source region 20, drain region 22, and gate region 24. Each of these electrodes is in ohmic contact with its corresponding region.

Although the present invention has been described in detail, it should be understood that various changes, substitutions and alterations can be made hereto without departing from the sphere and scope of the invention as defined by the appended claims.

What is claimed is:

1. A junction field effect transistor, comprising:
a semiconductor wafer having a (110) surface orientation;
a source region formed on the semiconductor wafer;
a drain region formed on the semiconductor wafer; and
a channel region of a p-conductivity type formed between the source region and the drain region, wherein the channel region is oriented along a <110> direction of the semiconductor wafer.

2. The junction field effect transistor of claim 1, further comprising a gate region of an n-conductivity type, and wherein the source region and the drain region comprise p-conductivity type regions.

3. The junction field effect transistor of claim 1, wherein hole carriers flow in a direction substantially parallel to the <110> direction of the semiconductor wafer.

4. The junction field effect transistor of claim 2, further comprising:
a source electrode region in ohmic contact with the source region;
a drain electrode region in ohmic contact with the drain region; and
a gate electrode region in ohmic contact with the gate region.

5. The junction field effect transistor of claim 1, wherein the transistor exhibits an increased drive current based at least in part upon increased hole mobility in the <110> direction of the semiconductor wafer.

6. A junction field effect transistor, comprising:
a semiconductor wafer having a (110) surface orientation;
a source region formed on the semiconductor wafer;
a drain region formed on the semiconductor wafer; and
a channel region of a p-conductivity type formed between the source region and the drain region, wherein the channel region is oriented along a <100> direction of the semiconductor wafer.

7. The junction field effect transistor of claim 6, further comprising a gate region of an n-conductivity type, and wherein the source region and the drain region comprise p-conductivity type regions.

8. The junction field effect transistor of claim 6, wherein hole carriers flow in a direction substantially parallel to the <100> direction of the semiconductor wafer.

9. The junction field effect transistor of claim 7, further comprising:
a source electrode region in ohmic contact with the source region;
a drain electrode region in ohmic contact with the drain region; and
a gate electrode region in ohmic contact with the gate region.

10. The junction field effect transistor of claim 6, wherein the transistor exhibits an increased drive current based at least in part upon increased hole mobility in the <100> direction of the semiconductor wafer.

11. A junction field effect transistor, comprising:
a semiconductor wafer having a (100) surface orientation;
a source region formed on the semiconductor wafer;
a drain region formed on the semiconductor wafer; and
a channel region of a p-conductivity type formed between the source region and the drain region, wherein the channel region is oriented in a direction along a <100> direction of the semiconductor wafer.

12. The junction field effect transistor of claim 11, further comprising a gate region of an n-conductivity type, and wherein the source region and the drain region comprise p-conductivity type regions.

13. The junction field effect transistor of claim 11, wherein hole carriers flow in a direction substantially parallel to the <100> direction of the semiconductor wafer.

14. The junction field effect transistor of claim 12, further comprising:
a source electrode region in ohmic contact with the source region;
a drain electrode region in ohmic contact with the drain region; and
a gate electrode region in ohmic contact with the gate region.

15. The junction field effect transistor of claim 11, wherein the transistor exhibits an increased drive current based at least in part upon increased hole mobility in the <100> direction of the semiconductor wafer.

16. The junction field effect transistor of claim 11, wherein the semiconductor wafer has a <100> notch orientation.

17. The junction field effect transistor of claim 11, wherein the semiconductor wafer has a <110> notch orientation.

18. A method for forming a junction field effect transistor, the method comprising:
providing a semiconductor wafer having a (110) surface orientation;
forming a source region on the semiconductor wafer;
forming a drain region on the semiconductor wafer;
forming a channel region of a p-conductivity type between the source region and the drain region, wherein the channel region is oriented along a <110> direction of the semiconductor wafer; and
forming a gate region of an n-conductivity type.

19. The method of claim 18, further comprising:
forming a source electrode region in ohmic contact with the source region;
forming a drain electrode region in ohmic contact with the drain region; and
forming a gate electrode region in ohmic contact with the gate region.

20. The method of claim 18, wherein the semiconductor wafer comprises a <100> notch orientation.

21. The method of claim 18, wherein the semiconductor wafer comprises a <110> notch orientation.

22. A method for forming a junction field effect transistor, the method comprising:
providing a semiconductor wafer having a (100) surface orientation;
forming a source region on the semiconductor wafer;
forming a drain region on the semiconductor wafer;
forming a channel region of a p-conductivity type between the source region and the drain region, wherein the channel region is oriented along a <100> direction of the semiconductor wafer; and
forming a gate region of an n-conductivity type.

23. The method of claim 22, further comprising:
forming a source electrode region in ohmic contact with the source region;
forming a drain electrode region in ohmic contact with the drain region; and
forming a gate electrode region in ohmic contact with the gate region.

24. The method of claim 22, wherein the semiconductor wafer comprises a <100> notch orientation.

25. The method of claim 22 wherein the semiconductor wafer comprises a <110> notch orientation.
